(19) United States
(12) Patent Application Publication
(10) Pub. No.: US 2026/0101711 A1
(43) Pub. Date: Apr. 9, 2026

(54) ROBOT SYSTEM, ALIGNER, AND ALIGNING SEMICONDUCTOR SUBSTRATE

(71) Applicant: KAWASAKI JUKOGYO KABUSHIKI KAISHA, Kobe-shi, Hyogo (JP)

(72) Inventors: Shinya KITANO, Kobe-shi (JP); Tadahiro KATO, Kobe-shi (JP); Atsushi NAKAYA, Kobe-shi (JP); Yohei ARAI, Kobe-shi (JP)

(73) Assignee: KAWASAKI JUKOGYO KABUSHIKI KAISHA, Kobe-shi, Hyogo (JP)

(21) Appl. No.: 19/113,631

(22) PCT Filed: Oct. 5, 2023
(86) PCT No.: PCT/JP2023/036406

§ 371 Date: Mar. 20, 2025

(30) Foreign Application Priority Data
Oct. 5, 2022 (JP) 2022-160989

(51) Int. Cl. H10P 72/50

(52) U.S. Cl. CPC H10P 72/53

(57) ABSTRACT

A robot system includes a controller configured or programmed to perform a position identification control without stopping rotation of a mount performed to detect a mark, and perform an alignment control without stopping the rotation of the mount and while maintaining a rotation direction of the mount after a position of the mark is identified.

### TECHNICAL FIELD

The present disclosure relates to a robot system, an aligner, and a method for aligning a semiconductor substrate.

### BACKGROUND ART

Conventionally, an aligner that aligns a semiconductor substrate is known. For example, Japanese Patent Laid-Open No. 2021-044548 discloses an aligner that aligns a semiconductor substrate including a notch on its outer periphery.

### PRIOR ART

### Patent Document

Patent Documents 1: Japanese Patent Laid-Open No. 2021-044548

### SUMMARY OF THE INVENTION

Although not clearly described in Japanese Patent Laid-Open No. 2021-044548, in a conventional aligner such as that described in Japanese Patent Laid-Open No. 2021-044548, after a mount on which a semiconductor substrate is placed is rotated to detect the position of a notch, the rotation of the mount is temporarily stopped and then detection data is analyzed to identify the position of the notch. After the position of the notch is identified, the mount is conceivably rotated in a direction closer to an alignment position, which is a target position, as viewed from the position of the notch such that the notch is located at the alignment position. Therefore, in the conventional aligner such as that described in Japanese Patent Laid-Open No. 2021-044548, it is necessary to decelerate and accelerate rotation of the mount in order to temporarily stop the rotation of the mount or change the rotation direction of the mount, and the overall time required to align the semiconductor substrate conceivably tends to be increased. Therefore, a configuration capable of shortening the overall time required to align the semiconductor substrate is desired.

The present disclosure is intended to solve the above problem. The present disclosure aims to provide a robot system, an aligner, and a method for aligning a semiconductor substrate each capable of shortening the overall time required to align the semiconductor substrate.

In order to attain the aforementioned object, a robot system according to a first aspect of the present disclosure includes a substrate transport robot to transport a semiconductor substrate including a mark on an outer periphery of the semiconductor substrate for circumferential positioning, and an aligner to align the semiconductor substrate. The aligner includes a mount rotatable around a rotation axis with the semiconductor substrate placed thereon, a detector to detect the mark of the semiconductor substrate that is placed on the mount and rotated around the rotation axis, and a controller configured or programmed to perform a position identification control to identify a position of the mark based on a result of detection of the mark by the detector, and perform an alignment control to rotate the mount so as to align the semiconductor substrate based on an identified position of the mark. The controller is configured or programmed to perform the position identification control without stopping rotation of the mount performed to detect the mark, and perform the alignment control without stopping the rotation of the mount and while maintaining a rotation direction of the mount after the position of the mark is identified.

In the robot system according to the first aspect of the present disclosure, as described above, the controller is configured or programmed to perform the position identification control without stopping the rotation of the mount performed to detect the mark, and perform the alignment control without stopping the rotation of the mount and while maintaining the rotation direction of the mount after the position of the mark is identified. Accordingly, the mount continues to be rotated in the same direction without being stopped from when the rotation of the mount is started in order to detect the mark to when the mark is located at an alignment position, and thus the time required to decelerate and accelerate the rotation of the mount can be shortened as compared with a case in which the rotation of the mount is temporarily stopped or a case in which the rotation direction of the mount is changed midway, for example. Consequently, the overall time required to align the semiconductor substrate can be shortened.

In order to attain the aforementioned object, an aligner according to a second aspect of the present disclosure is an aligner operable to align a semiconductor substrate including a mark on an outer periphery of the semiconductor substrate for circumferential positioning, and includes a mount rotatable around a rotation axis with the semiconductor substrate placed thereon, a detector to detect the mark of the semiconductor substrate that is placed on the mount and rotated around the rotation axis, and a controller configured or programmed to perform a position identification control to identify a position of the mark based on a result of detection of the mark by the detector, and perform an alignment control to rotate the mount so as to align the semiconductor substrate based on an identified position of the mark. The controller is configured or programmed to perform the position identification control without stopping rotation of the mount performed to detect the mark, and perform the alignment control without stopping the rotation of the mount and while maintaining a rotation direction of the mount after the position of the mark is identified.

In the aligner according to the second aspect of the present disclosure, as described above, similarly to the robot system according to the first aspect, the controller is configured or programmed to perform the position identification control without stopping the rotation of the mount performed to detect the mark, and perform the alignment control without stopping the rotation of the mount and while maintaining the rotation direction of the mount after the position of the mark is identified. Accordingly, similarly to the robot system according to the first aspect, the time required to decelerate and accelerate the rotation of the mount can be shortened as compared with a case in which the rotation of the mount is temporarily stopped or a case in which the rotation direction of the mount is changed midway, for example.

Consequently, similarly to the robot system according to the first aspect, the overall time required to align the semiconductor substrate can be shortened.

In order to attain the aforementioned object, a method for aligning a semiconductor substrate according to a third aspect of the present disclosure is a method for aligning a semiconductor substrate including a mark on an outer periphery of the semiconductor substrate for circumferential positioning, and includes detecting the mark of the semiconductor substrate that is placed on a mount and rotated around a rotation axis, identifying a position of the mark based on a result of detection of the mark without stopping rotation of the mount performed to detect the mark, and rotating the mount so as to align the semiconductor substrate based on an identified position of the mark without stopping the rotation of the mount and while maintaining a rotation direction of the mount after the position of the mark is identified.

In the method for aligning the semiconductor substrate according to the third aspect of the present disclosure, as described above, the position of the mark is identified based on the result of the detection of the mark without stopping the rotation of the mount performed to detect the mark, and after the position of the mark is identified, the mount is rotated so as to align the semiconductor substrate based on the identified position of the mark without stopping the rotation of the mount and while maintaining the rotation direction of the mount. Accordingly, the mount continues to be rotated in the same direction without being stopped from when the mount is rotated in order to detect the mark to when the mark is located at an alignment position, and thus when the position of the mark is identified after the rotation of the mount performed to detect the mark is stopped, the time required to decelerate and accelerate the rotation of the mount can be shortened as compared with a case in which the rotation of the mount is temporarily stopped or a case in which the rotation direction of the mount is changed midway, for example. Consequently, similarly to the robot system according to the first aspect, the overall time required to align the semiconductor substrate 110 can be shortened.

According to the present disclosure, as described above, it is possible to provide the robot system, the aligner, and the method for aligning the semiconductor substrate each capable of shortening the overall time required to align the semiconductor substrate.

### BRIEF DESCRIPTION OF THE DRAWINGS

FIG. 1 is a perspective view showing the overall configuration of a robot system according to an embodiment of the present disclosure.

FIG. 2 is a schematic view showing a state before a mount is rotated to detect a mark in an aligner according to the embodiment of the present disclosure.

FIG. 3 is a schematic view showing a state in which the mark overlaps with a detector in a plan view in the aligner according to the embodiment of the present disclosure.

FIG. 4 is a diagram for illustrating the position identification control and alignment control of the aligner according to the embodiment of the present disclosure.

FIG. 5 is a schematic view showing a state in which the mark is located at an alignment position in the aligner according to the embodiment of the present disclosure.

FIG. 6 is a schematic view for illustrating the rotation direction of the mount of the aligner according to the embodiment of the present disclosure.

FIG. 7 is a flowchart showing alignment of a semiconductor substrate by the aligner according to the embodiment of the present disclosure.

FIG. 8 is a schematic view showing an aligner according to a first modified example of the present disclosure.

FIG. 9 is a schematic view showing a semiconductor substrate according to a second modified example of the present disclosure.

FIG. 10 is a schematic view for illustrating the rotation direction of a mount of an aligner according to a third modified example of the present disclosure.

FIG. 11 is a diagram for illustrating the position identification control and alignment control of an aligner according to a fourth modified example of the present disclosure.

### MODES FOR CARRYING OUT THE INVENTION

An embodiment embodying the present disclosure is hereinafter described on the basis of the drawings.

### Configuration of Robot System

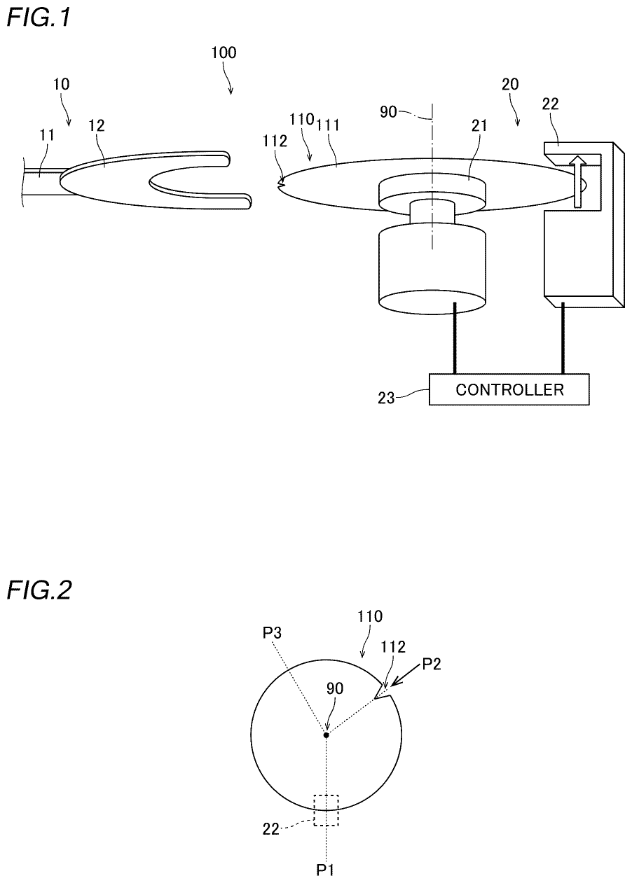

The configuration of a robot system 100 according to the embodiment of the present disclosure is now described with reference to FIGS. 1 to 6.

### Overall Configuration of Robot System

As shown in FIG. 1, the robot system 100 includes a substrate transport robot 10 to transport a semiconductor substrate 110, and an aligner 20 to align the semiconductor substrate 110. The semiconductor substrate 110 includes a mark 112 formed on a portion of an outer periphery 111 for circumferential positioning. Only one mark 112 is provided on the semiconductor substrate 110. The mark 112 is a notch. Alignment of the semiconductor substrate 110 is performed to correct the substrate transport operation of the robot system 100. The substrate transport operation of the robot system 100 includes, for example, the operation of the robot system 10 to pick up the semiconductor substrate 110, the operation of the robot system 10 to place the semiconductor substrate 110, etc.

The substrate transport robot 10 includes a hand 11 to hold the semiconductor substrate 110, and a robot arm 12 having a distal end to which the hand 11 is attached. The substrate transport robot 10 is a horizontal articulated robot, for example.

The aligner 20 includes a mount 21 rotatable around a rotation axis 90 with the semiconductor substrate 110 placed thereon. The semiconductor substrate 110 is suctioned by the mount 21 so as to be rotatable while being placed on the mount 21, or a mounting surface of the mount 21 is processed to generate a frictional force between the mount 21 and the semiconductor substrate 110. In such a case, the center of gravity or the center of the semiconductor substrate 110 placed on the mount 21 may be misaligned with the rotation axis 90 of the mount 21.

The aligner 20 includes a detector 22 to detect the mark 112 of the semiconductor substrate 110 that is placed on the mount 21 and rotated around the rotation axis 90. The detector 22 includes a light emitter that emits light for detection, and a light receiver to receive the light emitted from the light emitter. The light emitter and the light receiver interpose the outer periphery 111 of the semiconductor substrate 110 therebetween. The detector 22 detects the mark 112 formed on the outer periphery 111 of the semiconductor substrate 110 based on whether or not the light receiver receives the light emitted from the light emitter in a state in which the semiconductor substrate 110 is rotated around the rotation axis 90 by rotating the mount 21. That is, the detector 22 is a transmission sensor. Only one detector 22 is provided in the aligner 20. The detector 22 may be, for example, a reflective sensor or a camera including an image sensor such as a charge coupled device (CCD) or a complementary metal oxide semiconductor (CMOS).

The aligner 20 includes a controller 23 to control rotation of the mount 21. The controller 23 includes, for example, a processor such as a central processing unit (CPU) and a memory to store information. The controller 23 may be a controller dedicated to the aligner 20, or may also serve as a controller that controls the robot 10.

### Position Identification Control of Controller

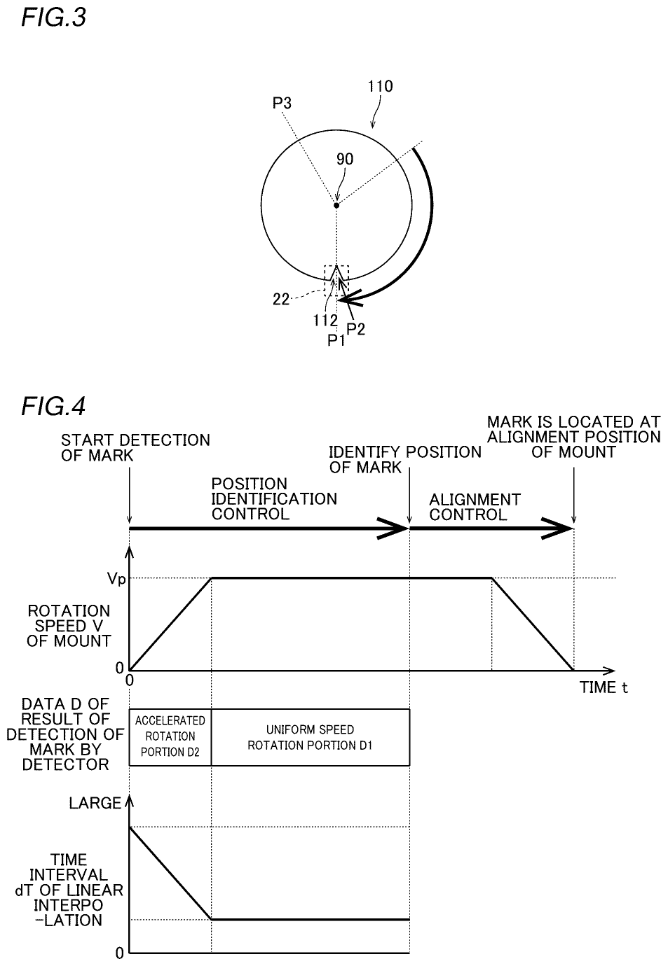

As shown in FIGS. 2 and 3, the controller 23 performs a position identification control to identify the position P2 of the mark 112 based on the result of detection of the mark 112 by the detector 22. Specifically, the controller 23 rotates the mount 21 in order for the detector 22 to detect the mark 112. As shown in FIG. 4, the controller 23 acquires data D of the result of detection of the mark 112 by the detector 22 while rotating the mount 21. While rotating the mount 21, the controller 23 analyzes the acquired data D one by one in the order in which it is acquired until the position P2 of the mark 112 is identified. In other words, the controller 23 performs the position identification control without stopping rotation of the mount performed to detect the mark 112.

The controller 23 performs the position identification control using an accelerated rotation portion D2 detected while rotation of the mount 21 is accelerated in addition to a uniform speed rotation portion D1 detected while the mount 21 is rotated at a uniform speed, among the data D. Specifically, after starting rotation of the mount 21, the controller 23 increases the rotation speed V of the mount 21 until it reaches a predetermined rotation speed Vp, and rotates the mount 21 at a uniform speed until the position P2 of the mark 112 is identified after the rotation speed V of the mount 21 reaches the predetermined rotation speed Vp. The controller 23 continues to acquire the data D from when rotation of the mount 21 is started to when the position P2 of the mark 112 is identified. The data D includes only the uniform speed rotation portion D1 and the accelerated rotation portion D2. The data D for detecting the mark 112 is sufficient when obtained by rotating the mount 21 by 360 degrees, and thus the rotation angle of the mount 21 corresponding to the uniform speed rotation portion D1 is less than 360 degrees. That is, the controller 23 performs the position identification control using the accelerated rotation portion D2 in addition to the uniform speed rotation portion DI detected while the mount 21 is rotated at a uniform speed by less than 360 degrees, among the data D.

The controller 23 performs the position identification control using the accelerated rotation portion D2 in which the time interval dT of linear interpolation for analyzing the data D has been adjusted according to the magnitude of the rotation speed of the mount 21, in addition to the uniform speed rotation portion D1, among the data D. Specifically, the controller 23 performs the position identification control using the accelerated rotation portion D2 in which the time interval dT of the linear interpolation has been adjusted to gradually decrease as the rotation speed of the mount 21 increases, in addition to the uniform speed rotation portion D1, among the data D. That is, the uniform speed rotation portion D1 of the data D used for the position identification control is linearly interpolated at a constant time interval dT. On the other hand, for the accelerated rotation portion D2 of the data D used for the position identification control, the time interval dT of linear interpolation in the accelerated rotation portion D2 is adjusted such that the rotation angle of the mount 21 per unit time corresponding to the uniform speed rotation portion D1 and the rotation angle of the mount 21 per unit time corresponding to the accelerated rotation portion D2 are substantially equal to each other.

### Alignment Control of Controller

The controller 23 performs an alignment control to rotate the mount 21 so as to align the semiconductor substrate 110 based on the identified position P2 of the mark 112. Specifically, as shown in FIGS. 3 and 5, after the position P2 of the mark 112 is identified, the controller 23 rotates the mount 21 until the mark 112 is located at the alignment position P3. The alignment position P3 is the target position of the mark 112 in the alignment control.

After the position P2 of the mark 112 is identified, the controller 23 performs the alignment control without stopping rotation of the mount 21 and while maintaining the rotation direction of the mount 21. That is, as shown in FIGS. 2, 3, and 5, the controller 23 continues to rotate the mount 21 in the same direction from when rotation of the mount 21 is started to detect the mark 112 by the detector 22 to when the mark 112 is located at the alignment position P3. FIGS. 2, 3, and 5 show an example in which the mount 21 is rotated clockwise.

When performing an eccentricity analysis control to analyze eccentricity, which is a deviation of the center of gravity or the center of the semiconductor substrate 110 with respect to the rotation axis 90 of the mount 21, the controller 23 performs the alignment control after the position P2 of the mark 112 is identified and after the mount 21 is rotated by at least about 180 degrees after starting rotation for identifying the position P2 of the mark 112. Specifically, when the eccentricity analysis control is required, even after the position P2 of the mark 112 is identified, the alignment control is not performed until the mount 21 is rotated by about 180 degrees or more, which is required for at least the eccentricity analysis control, after starting rotation for identifying the position P2 of the mark 112. The eccentricity analysis control is performed based on detection data for about 180 degrees of the outer periphery 111 of the semiconductor substrate 110 in order to detect the center of gravity or the center of the semiconductor substrate 110. Information on the center of gravity or the center of the semiconductor substrate 110 acquired by the eccentricity analysis control is used to correct the substrate transport operation of the robot system 100.

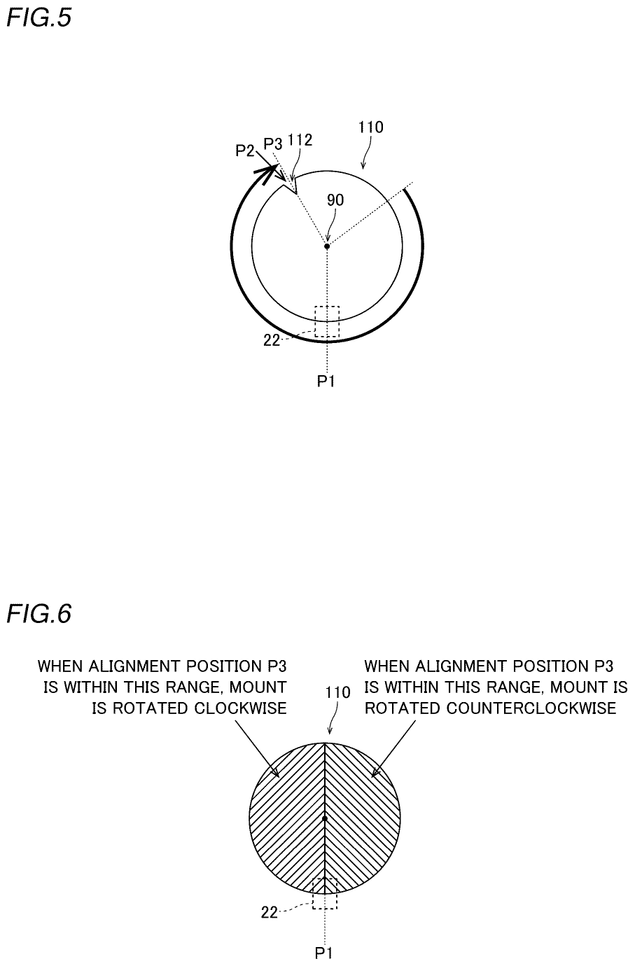

The controller 23 determines the rotation direction of the mount 21 for the detector 22 to detect the mark 112 based on the relationship between the position P1 of the detector 22 with respect to the mount 21 before rotation of the mount 21 and the alignment position P3. Specifically, as shown in FIG. 6, the controller 23 determines rotation of the mount 21 for the detector 22 to detect the mark 112, in a direction closer to the alignment position P3 as viewed from the position Pl of the detector 22 with respect to the mount 21 before rotation of the mount 21. That is, when the clockwise direction is closer to the alignment position P3 of the mount 21 as viewed from the position Pl of the detector 22 with respect to the mount 21 before rotation of the mount 21, the controller 23 continues to rotate the mount 21 clockwise after starting rotation of the mount 21 for the detector 22 to detect the mark 112, until the mark 112 is located at the alignment position P3. In other words, when the semiconductor substrate 110 is likened to a clock in FIG. 6, the mount 21 continues to be rotated counterclockwise when the alignment position P3 is within a range from 0 o'clock to 6 o'clock with the position P1 of the detector 22 in a 6 o'clock direction. When the counterclockwise direction is closer to the alignment position P3 as viewed from the position Pl of the detector 22 with respect to the mount 21 before rotation of the mount 21, the controller 23 continues to rotate the mount 21 counterclockwise after starting rotation of the mount 21 for the detector 22 to detect the mark 112, until the mark 112 is located at the alignment position P3. In other words, when the semiconductor substrate 110 is likened to a clock in FIG. 6, the mount 21 continues to be rotated clockwise when the alignment position P3 is within a range from 6 o'clock to 12 o'clock with the position P1 of the detector 22 in the 6 o'clock direction.

### Method for Aligning Semiconductor Substrate

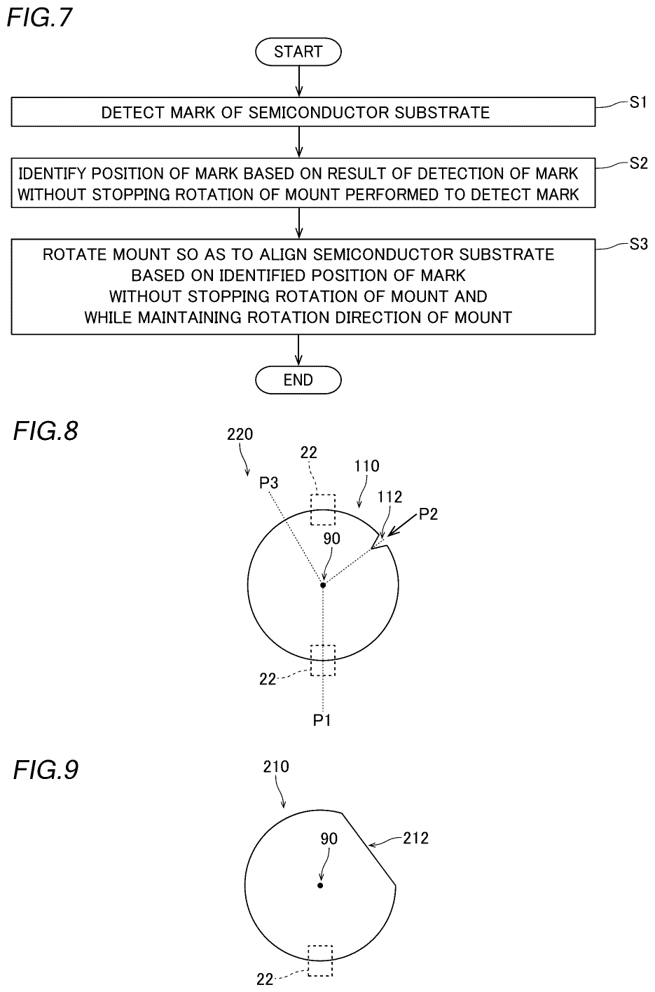

A method for aligning the semiconductor substrate 110 is now described with reference to FIG. 7.

As shown in FIG. 7, in step S1, the mark 112 of the semiconductor substrate 110 that is placed on the mount 21 and rotated around the rotation axis 90 is detected.

Next, in step S2, the position P2 of the mark 112 is identified based on the result of detection of the mark 112 without stopping rotation of the mount 21 performed to detect the mark 112. The operation in step S2 is not started after the end of the operation in step S1, but is carried out substantially concurrently with the operation in step S1.

Next, in step S3, after the position P2 of the mark 112 is identified, the mount 21 is rotated so as to align the semiconductor substrate 110 based on the identified position P2 of the mark 112 without stopping the rotation of the mount 21 and while the rotation direction of the mount 21 is maintained.

### Advantages of Embodiment

According to this embodiment, the following advantages are achieved.

### Advantages of Robot System and Aligner

According to this embodiment, the controller 23 is configured or programmed to perform the position identification control without stopping rotation of the mount 21 performed to detect the mark 112, and perform the alignment control without stopping the rotation of the mount 21 and while maintaining the rotation direction of the mount 21 after the position P2 of the mark 112 is identified. Accordingly, the mount 21 continues to be rotated in the same direction without being stopped from when the mount 21 is rotated in order to detect the mark 112 to when the mark 112 is located at the alignment position P3, and thus the time required to decelerate and accelerate the rotation of the mount 21 can be shortened as compared with a case in which the rotation of the mount 21 is temporarily stopped or a case in which the rotation direction of the mount 21 is changed midway, for example. Consequently, the overall time required to align the semiconductor substrate 110 can be shortened.

According to this embodiment, the controller 23 is configured or programmed to perform the position identification control using the accelerated rotation portion D2 detected while rotation of the mount 21 is accelerated in addition to the uniform speed rotation portion DI detected while the mount 21 is rotated at a uniform speed, among the data D of the result of detection of the mark 112 by the detector 22. Accordingly, the rotation angle range of the mount 21 for acquiring the uniform speed rotation portion D1 required for the position identification control can be decreased by using the accelerated rotation portion D2 for the position identification control. Consequently, the time required for the position identification control can be shortened as compared with a case in which the accelerated rotation portion D2 is not used for the position identification control, and thus the overall time required to align the semiconductor substrate 110 can be further shortened.

According to this embodiment, the controller 23 is configured or programmed to perform the position identification control using the accelerated rotation portion D2 in addition to the uniform speed rotation portion D1 detected while the mount 21 is rotated at a uniform speed by less than 360 degrees, among the data D. Accordingly, as compared with a case in which the rotation angle of the mount 21 corresponding to the uniform speed rotation portion D1 is 360 degrees or more, the rotation angle range of the mount 21 for acquiring the uniform speed rotation portion DI can be decreased. Consequently, as compared with a case in which the rotation angle of the mount 21 corresponding to the uniform speed rotation portion D1 is 360 degrees or more, the time required for the position identification control can be shortened, and thus the overall time required to align the semiconductor substrate 110 can be further shortened.

According to this embodiment, the controller 23 is configured or programmed to perform the position identification control using the accelerated rotation portion D2 in which the time interval of the linear interpolation for analyzing the data D has been adjusted according to the magnitude of the rotation speed of the mount 21, in addition to the uniform speed rotation portion D1, among the data D. Accordingly, by adjusting the time interval dT of the linear interpolation for the accelerated rotation portion D2 such that the rotation angle of the mount 21 per unit time corresponding to the uniform speed rotation portion D1 is substantially equal to the rotation angle of the mount 21 per unit time corresponding to the accelerated rotation portion D2, the accuracy of the linear interpolation can be equal between the uniform speed rotation portion D1 and the accelerated rotation portion D2. Consequently, even when in addition to the uniform speed rotation portion D1, the accelerated rotation portion D2 is used for the position identification control, a decrease in the accuracy of the position identification control can be reduced or prevented.

According to this embodiment, the controller 23 is configured or programmed to perform the position identification control using the accelerated rotation portion D2 in which the time interval dT of the linear interpolation has been adjusted to gradually decrease as the rotation speed of the mount 21 increases, in addition to the uniform speed rotation portion D1, among the data D. Accordingly, the time interval dT of the linear interpolation for the accelerated rotation portion D2 can be adjusted such that the rotation angle of the mount 21 per unit time corresponding to the uniform speed rotation portion D1 is substantially equal to the rotation angle of the mount 21 per unit time corresponding to the accelerated rotation portion D2, and thus the accuracy of the linear interpolation can be reliably equal between the uniform speed rotation portion D1 and the accelerated rotation portion D2. Consequently, even when in addition to the uniform speed rotation portion D1, the accelerated rotation portion D2 is used for the position identification control, a decrease in the accuracy of the position identification control can be reliably reduced or prevented.

According to this embodiment, the controller 23 is configured or programmed to determine the rotation direction of the mount 21 for the detector 22 to detect the mark 112 based on the relationship between the position P1 of the detector 22 with respect to the mount 21 before rotation of the mount 21 and the alignment position P3, which is the target position of the mark 112 in the alignment control. Accordingly, based on the relationship between the position P1 of the detector 22 with respect to the mount 21 before rotation of the mount 21 and the alignment position P3, the rotation direction of the mount 21 can be determined such that the rotation angle range of the mount 21 until the mark 112 is located at the alignment position P3 becomes smaller in the alignment control performed after the position identification control. Consequently, the time required for the alignment control can be shortened as compared with a case in which the rotation direction of the mount 21 is determined without taking into consideration the relationship between the position P1 of the detector 22 with respect to the mount 21 before rotation of the mount 21 and the alignment position P3, and thus the overall time required to align the semiconductor substrate 110 can be further shortened.

According to this embodiment, the controller 23 is configured or programmed to rotate the mount 21 in the direction closer to the alignment position P3 as viewed from the position P1 of the detector 22 with respect to the mount 21 before rotation of the mount 21 in order for the detector 22 to detect the mark 112. Accordingly, in the alignment control performed after the position identification control, the rotation angle range of the mount 21 until the mark 112 is located at the alignment position P3 can be smaller as compared with a case in which the mount 21 is rotated in a direction farther away from the alignment position P3 as viewed from the position P1 of the detector 22 with respect to the mount 21 before rotation of the mount 21. Consequently, the time required for the alignment control can be shortened as compared with a case in which the mount 21 is rotated in a direction farther away from the alignment position P3 as viewed from the position P1 of the detector 22 with respect to the mount 21 before rotation of the mount 21, and thus the overall time required to align the semiconductor substrate 110 can be further shortened.

According to this embodiment, the controller 23 is configured or programmed to perform the alignment control after the position P2 of the mark 112 is identified and after the mount 21 is rotated by at least about 180 degrees after starting rotation for identifying the position P2 of the mark 112 when performing the eccentricity analysis control to analyze eccentricity, which is a deviation of the center of gravity or the center of the semiconductor substrate 110 with respect to the rotation axis 90 of the mount 21. Accordingly, when the eccentricity analysis control is required, even after the position P2 of the mark 112 is identified, the alignment control is not performed until the mount 21 is rotated by about 180 degrees or more, which is required for at least the eccentricity analysis control, after starting rotation for identifying the position P2 of the mark 112 such that the eccentricity analysis control can be reliably performed. Furthermore, rotation of the mount 21 can be performed in common for the position identification control and the eccentricity analysis control, and thus the overall time required to align the semiconductor substrate 110 can be further shortened.

According to this embodiment, the mark 112 is a notch. Accordingly, the overall time required to align the semiconductor substrate 110 in which the mark 112 is a notch can be shortened.

### Advantages of Method for Aligning Semiconductor Substrate

According to this embodiment, the position P2 of the mark 112 is identified based on the result of detection of the mark 112 without stopping rotation of the mount 21 performed to detect the mark 112, and after the position P2 of the mark 112 is identified, the mount 21 is rotated so as to align the semiconductor substrate 110 based on the identified position P2 of the mark 112 without stopping the rotation of the mount 21 and while maintaining the rotation direction of the mount 21. Accordingly, the mount 21 continues to be rotated in the same direction without being stopped from when the mount 21 is rotated in order to detect the mark 112 to when the mark 112 is located at the alignment position P3, and thus the time required to decelerate and accelerate the rotation of the mount 21 can be shortened as compared with a case in which the rotation of the mount 21 is temporarily stopped or a case in which the rotation direction of the mount 21 is changed midway, for example. Consequently, similarly to the advantages of the robot system 100 and the aligner 20, the overall time required to align the semiconductor substrate 110 can be shortened.

### Modified Examples

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which only one detector 22 is provided in the aligner 20 has been shown in the aforementioned embodiment, the present disclosure is not limited to this. In the present disclosure, as in an aligner 220 according to a first modified example shown in FIG. 8, two or more detectors 22 may be provided in the aligner 220. Accordingly, as compared with a case in which only one detector 22 is provided in the aligner 220, the rotation angle of the mount 21 for detecting the mark 112 can be decreased, and thus the time required for the position identification control can be shortened. FIG. 8 shows an example in which two detectors 22 are provided around the rotation axis 90 at an interval of about 180 degrees.

While the example in which the mark 112 is a notch has been shown in the aforementioned embodiment, the present disclosure is not limited to this. In the present disclosure, as in a semiconductor substrate 210 according to a second modified example shown in FIG. 9, a mark 212 may be an orientation flat. Accordingly, the overall time required to align the semiconductor substrate 210 including an orientation flat as the mark 212 can be reliably shortened.

While the example in which the controller 23 performs the alignment control after the position P2 of the mark 112 is identified and after the mount 21 is rotated by at least about 180 degrees after starting rotation for identifying the position P2 of the mark 112 when performing the eccentricity analysis control to analyze eccentricity, which is a deviation of the center of gravity or the center of the semiconductor substrate 110 with respect to the rotation axis 90 of the mount 21 has been shown in the aforementioned embodiment, the present disclosure is not limited to this. In the present disclosure, the controller may perform the alignment control after the position of the mark is identified regardless of whether or not the mount has been rotated by at least about 180 degrees since starting rotation for identifying the position of the mark when not performing the eccentricity analysis control to analyze eccentricity, which is a deviation of the center of gravity or the center of the semiconductor substrate with respect to the rotation axis of the mount.

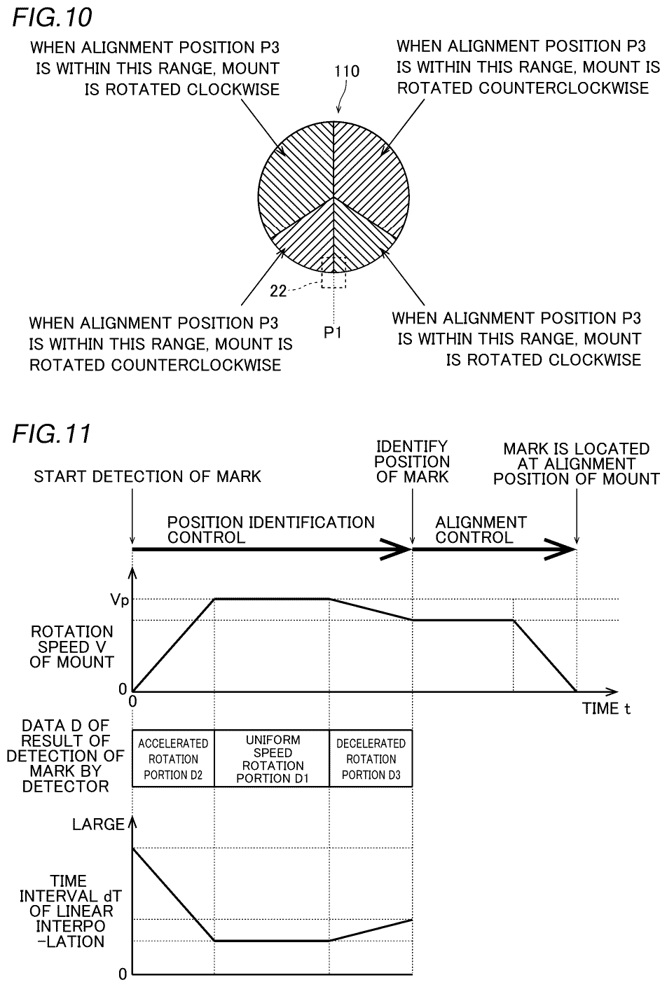

While the example in which the controller 23 determines the rotation direction of the mount 21 for the detector 22 to detect the mark 112 to be in the direction closer to the alignment position P3 as viewed from the position P1 of the detector 22 with respect to the mount 21 before rotation of the mount 21 has been shown in the aforementioned embodiment, the present disclosure is not limited to this. In the present disclosure, as in a third modified example shown in FIG. 10, the controller 23 may determine the rotation direction of the mount 21 for the detector 22 to detect the mark 112 based on which of three or more regions the alignment position P3 is in, rather than on which of two regions the alignment position P3 is in, as in a case in which the rotation direction of the mount 21 is determined to be in the direction closer to the alignment position P3 as viewed from the position P1 of the detector 22 with respect to the mount 21 before rotation of the mount 21, when the rotation direction of the mount 21 for the detector 22 to detect the mark 112 is determined based on the relationship between the position P1 of the detector 22 with respect to the mount 21 before rotation of the mount 21 and the alignment position P3. In the third modified example shown in FIG. 10, the rotation direction of the mount 21 is determined based on which of four regions the alignment position P3 of the mount 21 is in. Specifically, when the semiconductor substrate 110 is likened to a clock in FIG. 10, with the position P1 of the detector 22 in a 6 o'clock direction, the mount 21 continues to be rotated counterclockwise when the alignment position P3 is within a range from 0 o'clock to 4 o'clock or within a range from 6 o'clock to 8 o'clock, and continues to be rotated clockwise when the alignment position P3 of the semiconductor substrate 110 is within a range from 4 o'clock to 6 o'clock, within a range from 8 o'clock to 12 o'clock, or within a range from 4 o'clock to 6 o'clock.

While the example in which the controller 23 determines the rotation direction of the mount 21 for the detector 22 to detect the mark 112 based on the relationship between the position Pl of the detector 22 with respect to the mount 21 before rotation of the mount 21 and the alignment position P3 has been shown in the aforementioned embodiment, the present disclosure is not limited to this. In the present disclosure, the controller may determine the rotation direction of the mount for the detector to detect the mark without being based on the relationship between the position of the detector with respect to the mount before rotation of the mount and the alignment position.

The example in which the controller 23 performs the position identification control using the accelerated rotation portion D2 in which the time interval dT of the linear interpolation has been adjusted to gradually decrease as the rotation speed of the mount 21 increases, in addition to the uniform speed rotation portion D1, among the data D has been shown in the aforementioned embodiment. That is, while the example in which the controller 23 performs the position identification control using the accelerated rotation portion D2 in which the time interval dT of the linear interpolation for analyzing the data D has been adjusted according to the magnitude of the rotation speed of the mount 21, in addition to the uniform speed rotation portion D1, among the data D has been shown in the aforementioned embodiment, the present disclosure is not limited to this. In the present disclosure, the controller may perform the position identification control using an accelerated rotation portion in which the time interval of the linear interpolation has not been adjusted to gradually decrease as the rotation speed of the mount increases, in addition to the uniform speed rotation portion, among the data. That is, the controller may perform the position identification control using the accelerated rotation portion in which the time interval of the linear interpolation for analyzing the data has not been adjusted according to the magnitude of the rotation speed of the mount, in addition to the uniform speed rotation portion, among the data.

While the example in which the data D includes only the uniform speed rotation portion D1 and the accelerated rotation portion D2, and the controller 23 performs the position identification control using the uniform speed rotation portion D1 and the accelerated rotation portion D2, among the data D has been shown in the aforementioned embodiment, the present disclosure is not limited to this. In the present disclosure, as in a fourth modified example shown in FIG. 11, when data D includes a decelerated rotation portion D3 in addition to the uniform speed rotation portion D1 and the accelerated rotation portion D2, the controller 23 may perform the position identification control using the decelerated rotation portion D3 detected while rotation of the mount 21 is decelerated in addition to the uniform speed rotation portion D1 and the accelerated rotation portion D2, among the data D. Accordingly, when the data D includes the decelerated rotation portion D3 in addition to the uniform speed rotation portion D1 and the accelerated rotation portion D2, the rotation angle range of the mount 21 for acquiring the uniform speed rotation portion D1 required for the position identification control can be decreased by using the decelerated rotation portion D3 for the position identification control. Consequently, when the data D includes the decelerated rotation portion D3, the time required for the position identification control can be shortened as compared with a case in which the decelerated rotation portion D3 is not used for the position identification control, and thus the overall time required to align the semiconductor substrate 110 can be further shortened.

While the example in which the controller 23 performs the position identification control using the accelerated rotation portion D2 in addiction to the uniform speed rotation portion DI detected while the mount 21 is rotated at a uniform speed by less than 360 degrees, among the data D has been shown in the aforementioned embodiment, the present disclosure is not limited to this. In the present disclosure, the controller may perform the position identification control using the accelerated rotation portion in addition to a uniform speed rotation portion detected while the mount is rotated at a uniform speed by 360 degrees or more, among the data.

While the example in which the controller 23 performs the position identification control using the accelerated rotation portion D2 detected while rotation of the mount 21 is accelerated, in addiction to the uniform speed rotation portion D1 detected while the mount 21 is rotated at a uniform speed, among the data D of the result of detection of the mark 112 by the detector 22 has been shown in the aforementioned embodiment, the present disclosure is not limited to this. In the present disclosure, the controller may perform the position identification control using only the uniform speed rotation portion detected while the mount is rotating at a uniform speed, without using the accelerated rotation portion detected while rotation of the mount is accelerated, among the data of the result of detection of the mark by the detector.

While the example in which the detector 22 detects the mark 112 on the semiconductor substrate 110, and the controller 23 identifies the position P2 of the mark 112 based on the result of detection of the mark 112 by the detector 22 has been shown in the aforementioned embodiment, the present disclosure is not limited to this. In the present disclosure, the detector may detect a defect in the semiconductor substrate in addition to the mark on the semiconductor substrate, and the controller may identify the position of the defect based on the result of detection of the defect by the detector in addition to identifying the position of the mark based on the result of detection of the mark by the detector.

The functionality of the elements disclosed herein may be implemented using circuitry or processing circuitry that includes general purpose processors, special purpose processors, integrated circuits, application specific integrated circuits (ASICs), conventional circuitry and/or combinations thereof that are configured or programmed to perform the disclosed functionality. Processors are considered processing circuitry or circuitry as they include transistors and other circuitry therein. In the present disclosure, the circuitry, units, or means are hardware that carries out the recited functionality or hardware that is programmed to perform the recited functionality. The hardware may be hardware disclosed herein or other known hardware that is programmed or configured to carry out the recited functionality. When the hardware is a processor that may be considered a type of circuitry, the circuitry, means, or units are a combination of hardware and software, and the software is used to configure the hardware and/or processor.

### Aspects

It will be appreciated by those skilled in the art that the exemplary embodiments described above are specific examples of the following aspects.

### Item 1

A robot system comprising:
a substrate transport robot to transport a semiconductor substrate including a mark on an outer periphery of the semiconductor substrate for circumferential positioning; and
an aligner to align the semiconductor substrate; wherein
the aligner includes:
   a mount rotatable around a rotation axis with the semiconductor substrate placed thereon;
   a detector to detect the mark of the semiconductor substrate that is placed on the mount and rotated around the rotation axis; and
   a controller configured or programmed to perform a position identification control to identify a position of the mark based on a result of detection of the mark by the detector, and perform an alignment control to rotate the mount so as to align the semiconductor substrate based on an identified position of the mark; and

the controller is configured or programmed to perform the position identification control without stopping rotation of the mount performed to detect the mark, and perform the alignment control without stopping the rotation of the mount and while maintaining a rotation direction of the mount after the position of the mark is identified.

### Item 2

The robot system according to item 1, wherein the controller is configured or programmed to perform the position identification control using an accelerated rotation portion detected while the rotation of the mount is accelerated in addition to a uniform speed rotation portion detected while the mount is rotated at a uniform speed, among data of the result of the detection of the mark by the detector.

### Item 3

The robot system according to item 2, wherein the controller is configured or programmed to perform the position identification control using the accelerated rotation portion in addition to the uniform speed rotation portion detected while the mount is rotated at the uniform speed by less than 360 degrees, among the data.

### Item 4

The robot system according to item 2 or 3, wherein the controller is configured or programmed to perform the position identification control using a decelerated rotation portion detected while the rotation of the mount is decelerated in addition to the uniform speed rotation portion and the accelerated rotation portion, among the data.

### Item 5

The robot system according to any one of items 2 to 4, wherein the controller is configured or programmed to perform the position identification control using the accelerated rotation portion in which a time interval of linear interpolation for analyzing the data has been adjusted according to a magnitude of a rotation speed of the mount, in addition to the uniform speed rotation portion, among the data.

### Item 6

The robot system according to item 5, wherein the controller is configured or programmed to perform the position identification control using the accelerated rotation portion in which the time interval of the linear interpolation has been adjusted to gradually decrease as the rotation speed of the mount increases, in addition to the uniform speed rotation portion, among the data.

### Item 7

The robot system according to any one of items 1 to 6, wherein the controller is configured or programmed to determine the rotation direction of the mount for the detector to detect the mark based on a relationship between a position of the detector with respect to the mount before the rotation of the mount and an alignment position, which is a target position of the mark in the alignment control.

### Item 8

The robot system according to item 7, wherein the controller is configured or programmed to determine the rotation direction of the mount for the detector to detect the mark to be in a direction closer to the alignment position as viewed from the position of the detector with respect to the mount before the rotation of the mount.

### Item 9

The robot system according to any one of items 1 to 8, wherein the controller is configured or programmed to perform the alignment control after the position of the mark is identified and after the mount is rotated by at least about 180 degrees after starting the rotation for identifying the position of the mark when performing an eccentricity analysis control to analyze eccentricity, which is a deviation of a center of gravity or a center of the semiconductor substrate with respect to the rotation axis of the mount.

### Item 10

The robot system according to any one of items 1 to 9, wherein the mark is a notch.

### Item 11

The robot system according to any one of items 1 to 9, wherein the mark is an orientation flat.

### Item 12

An aligner operable to align a semiconductor substrate including a mark on an outer periphery of the semiconductor substrate for circumferential positioning, the aligner comprising:
a mount rotatable around a rotation axis with the semiconductor substrate placed thereon;
a detector to detect the mark of the semiconductor substrate that is placed on the mount and rotated around the rotation axis; and
a controller configured or programmed to perform a position identification control to identify a position of the mark based on a result of detection of the mark by the detector, and perform an alignment control to rotate the mount so as to align the semiconductor substrate based on an identified position of the mark; wherein
the controller is configured or programmed to perform the position identification control without stopping rotation of the mount performed to detect the mark, and perform the alignment control without stopping the rotation of the mount and while maintaining a rotation direction of the mount after the position of the mark is identified.

### Item 13

A method for aligning a semiconductor substrate including a mark on an outer periphery of the semiconductor substrate for circumferential positioning, the method comprising:
detecting the mark of the semiconductor substrate that is placed on a mount and rotated around a rotation axis;
identifying a position of the mark based on a result of detection of the mark without stopping rotation of the mount performed to detect the mark; and
rotating the mount so as to align the semiconductor substrate based on an identified position of the mark without stopping the rotation of the mount and while maintaining a rotation direction of the mount after the position of the mark is identified.

1. A robot system comprising:
a substrate transport robot to transport a semiconductor substrate including a mark on an outer periphery of the semiconductor substrate for circumferential positioning; and
an aligner to align the semiconductor substrate; wherein
the aligner includes:
a mount rotatable around a rotation axis with the semiconductor substrate placed thereon;
a detector to detect the mark of the semiconductor substrate that is placed on the mount and rotated around the rotation axis; and
a controller configured or programmed to perform a position identification control to identify a position of the mark based on a result of detection of the mark by the detector, and perform an alignment control to rotate the mount so as to align the semiconductor substrate based on an identified position of the mark; and
the controller is configured or programmed to perform the position identification control without stopping rotation of the mount performed to detect the mark, and perform the alignment control without stopping the rotation of the mount and while maintaining a rotation direction of the mount after the position of the mark is identified.

2. The robot system according to claim 1, wherein the controller is configured or programmed to perform the position identification control using an accelerated rotation portion detected while the rotation of the mount is accelerated in addition to a uniform speed rotation portion detected while the mount is rotated at a uniform speed, among data of the result of the detection of the mark by the detector.

3. The robot system according to claim 2, wherein the controller is configured or programmed to perform the position identification control using the accelerated rotation portion in addition to the uniform speed rotation portion detected while the mount is rotated at the uniform speed by less than 360 degrees, among the data.

4. The robot system according to claim 2, wherein the controller is configured or programmed to perform the position identification control using a decelerated rotation portion detected while the rotation of the mount is decelerated in addition to the uniform speed rotation portion and the accelerated rotation portion, among the data.

5. The robot system according to claim 2, wherein the controller is configured or programmed to perform the position identification control using the accelerated rotation portion in which a time interval of linear interpolation for analyzing the data has been adjusted according to a magnitude of a rotation speed of the mount, in addition to the uniform speed rotation portion, among the data.

6. The robot system according to claim 5, wherein the controller is configured or programmed to perform the position identification control using the accelerated rotation portion in which the time interval of the linear interpolation has been adjusted to gradually decrease as the rotation speed of the mount increases, in addition to the uniform speed rotation portion, among the data.

7. The robot system according to claim 1, wherein the controller is configured or programmed to determine the rotation direction of the mount for the detector to detect the mark based on a relationship between a position of the detector with respect to the mount before the rotation of the mount and an alignment position, which is a target position of the mark in the alignment control.

8. The robot system according to claim 7, wherein the controller is configured or programmed to determine the rotation direction of the mount for the detector to detect the mark to be in a direction closer to the alignment position as viewed from the position of the detector with respect to the mount before the rotation of the mount.

9. The robot system according to claim 1, wherein the controller is configured or programmed to perform the alignment control after the position of the mark is identified and after the mount is rotated by at least about 180 degrees after starting the rotation for identifying the position of the mark when performing an eccentricity analysis control to analyze eccentricity, which is a deviation of a center of gravity or a center of the semiconductor substrate with respect to the rotation axis of the mount.

10. The robot system according to claim 1, wherein the mark is a notch.

11. The robot system according to claim 1, wherein the mark is an orientation flat.

12. An aligner operable to align a semiconductor substrate including a mark on an outer periphery of the semiconductor substrate for circumferential positioning, the aligner comprising:
a mount rotatable around a rotation axis with the semiconductor substrate placed thereon;
a detector to detect the mark of the semiconductor substrate that is placed on the mount and rotated around the rotation axis; and
a controller configured or programmed to perform a position identification control to identify a position of the mark based on a result of detection of the mark by the detector, and perform an alignment control to rotate the mount so as to align the semiconductor substrate based on an identified position of the mark; wherein
the controller is configured or programmed to perform the position identification control without stopping rotation of the mount performed to detect the mark, and perform the alignment control without stopping the rotation of the mount and while maintaining a rotation direction of the mount after the position of the mark is identified.

13. A method for aligning a semiconductor substrate including a mark on an outer periphery of the semiconductor substrate for circumferential positioning, the method comprising:
detecting the mark of the semiconductor substrate that is placed on a mount and rotated around a rotation axis;
identifying a position of the mark based on a result of detection of the mark without stopping rotation of the mount performed to detect the mark; and
rotating the mount so as to align the semiconductor substrate based on an identified position of the mark without stopping the rotation of the mount and while maintaining a rotation direction of the mount after the position of the mark is identified.
